(19) United States
(12) Patent Application Publication
(10) Pub. No.: US 2016/0064488 A1
(43) Pub. Date: Mar. 3, 2016

(54) NITRIDE BASED SEMICONDUCTOR DEVICE

(71) Applicant: ROHM CO., LTD., Kyoto (JP)

(72) Inventors: Shinya TAKADO, Kyoto (JP); Norikazu ITO, Kyoto (JP); Junichi KASHIWAGI, Kyoto (JP); Hirokuni ASAMIZU, Kyoto (JP)

(73) Assignee: ROHM CO., LTD., Kyoto (JP)

(21) Appl. No.: 14/935,343

(22) Filed: Nov. 6, 2015

Related U.S. Application Data
(63) Continuation of application No. PCT/JP2014/062437, filed on May 9, 2014.

(30) Foreign Application Priority Data
May 9, 2013 (JP) 2013-099233

(51) Int. Cl. H01L 29/15; H01L 29/207; H01L 29/205; H01L 29/778

(52) U.S. Cl. CPC H01L 29/155; H01L 29/7783; H01L 29/157; H01L 29/207; H01L 29/205

(57) ABSTRACT

A nitride based semiconductor device includes: a substrate; a first buffer layer disposed on the substrate; a second buffer layer disposed on the first buffer layer; a third buffer layer disposed on the second buffer layer, the third buffer layer including an AlGaN-based nitride semiconductor; a fourth buffer layer disposed on the third buffer layer, the fourth buffer layer including a GaN-based nitride semiconductor; a barrier layer disposed on the fourth buffer layer, the barrier layer including an AlGaN-based nitride semiconductor; and a source electrode and a drain electrode, each disposed on the barrier layer, and a gate electrode disposed between the source electrode and the drain electrode, wherein the third buffer layer is subjected to lattice relaxation. There can be provided a nitride based semiconductor device capable of reducing a leakage current and improving breakdown capability.

### CROSS REFERENCE TO RELATED APPLICATIONS

This is a continuation application (CA) of PCT Application No. PCT/JP2014/062437, filed on May 9, 2014, which claims priority to Japan Patent Application No. P2013-099233 filed on May 9, 2013 and is based upon and claims the benefit of priority from prior Japanese Patent Applications P2013-099233 filed on May 9, 2013 and PCT Application No. PCT/JP2014/062437, filed on May 9, 2014, the entire contents of each of which are incorporated herein by reference.

### FIELD

The embodiment described herein relates to a nitride based semiconductor device. In particular, the embodiment relates to a nitride based semiconductor device of which a leakage current is reduced and a breakdown capability is improved.

### BACKGROUND

In nitride based semiconductor devices having High Electron Mobility Transistor (HEMT) structure, there have been proposed various kinds of technologies for reducing a leakage current by doping impurities, e.g. carbon (C).

There have been also disclosed a nitride semiconductor element capable of accommodating GaN electron transfer layers of wide range of thickness so as to allow greater freedom of device design, and a nitride semiconductor element package which is excellent in a breakdown voltage and reliability.

### SUMMARY

The embodiment provides a nitride based semiconductor device capable of reducing a leakage current and improving breakdown capability.

According to one aspect of the embodiment, there is provided a nitride based semiconductor device comprising: a substrate; a first buffer layer disposed on the substrate; a second buffer layer disposed on the first buffer layer; a third buffer layer disposed on the second buffer layer, the third buffer layer comprising an AlGaN-based nitride semiconductor; a fourth buffer layer disposed on the third buffer layer, the fourth buffer layer comprising a GaN-based nitride semiconductor; a barrier layer disposed on the fourth buffer layer, the barrier layer comprising an AlGaN-based nitride semiconductor; and a source electrode and a drain electrode, each disposed on the barrier layer, and a gate electrode disposed between the source electrode and the drain electrode, wherein the third buffer layer is subjected to lattice relaxation.

According to the embodiment, there can be provided the nitride based semiconductor device capable of reducing the leakage current and improving the breakdown capability.

### BRIEF DESCRIPTION OF DRAWINGS

FIG. 1 is a schematic cross-sectional structure diagram of a nitride based semiconductor device according to the embodiment.

FIG. 2 is an explanatory diagram for a vertical leakage current IᵣV and a horizontal leakage current IᵣH with respect to a total leakage current IᵣT, in the nitride based semiconductor device according to the embodiment.

FIG. 3A is an explanatory diagram for the vertical leakage current IᵣV and the horizontal leakage current IᵣH with respect to the total leakage current IᵣT, in the case of executing etching in the arrow direction E to artificially form an OFF state of the transistor, in the nitride based semiconductor device according to the embodiment.

FIG. 3B is a diagram showing a relationship between the total leakage current IᵣT and voltage Vᵣ applied between source/drain, using the thickness of an AlGaN monolayer or a super lattice buffer layer as a parameter.

FIG. 4A is a diagram showing a relationship between the vertical leakage current IᵣV and the voltage Vᵣ applied between source/drain, using the thickness of the AlGaN monolayer or the super lattice buffer layer as a parameter, in the nitride based semiconductor device according to the embodiment.

FIG. 4B is a diagram showing a rate of a vertical component in the voltage Vᵣ=400V applied between source/drain, in each of the AlGaN monolayer, the number of pairs of super lattices is 20, and the number of pairs of the super lattices is 40.

FIG. 5A is an explanatory diagram for the vertical leakage current IᵣV and the horizontal leakage current IᵣH with respect to the total leakage current IᵣT in the case of artificially forming an OFF state of the transistor by fixing the total layer thickness, changing the layer thickness ratio between a GaN buffer layer 16 and an AlGaN buffer layer 28, and executing the etched in the arrow direction E, in the nitride based semiconductor device according to the embodiment.

FIG. 5B is a diagram showing a relationship between the total leakage current IᵣT and the voltage Vᵣ applied between source/drain.

FIG. 6A is an explanatory diagram for the vertical leakage current IᵣV and the horizontal leakage current IᵣH with respect to the total leakage current IᵣT, in the case of executing etching in the arrow direction E to artificially form an OFF state of the transistor, in the nitride based semiconductor device according to the embodiment.

FIG. 6B is a diagram showing a relationship between the vertical leakage current IᵣV and horizontal leakage current IᵣH in applied voltage is 400V, and the etched depth t from the AlGaN layer surface.

FIG. 7 is a schematic cross-sectional structure diagram of a nitride based semiconductor device applied to a simulation of energy band structure, in the nitride based semiconductor device according to the embodiment.

FIG. 8 shows numerical examples of the Al composition (%), the layer thickness (nm), the a-axis lattice constant a (angstrom), and the distortion (%) in each of the AlGaN barrier layer 18, the GaN buffer layer 16, and the AlGaN buffer layer 28 in a normal state, in the nitride based semiconductor device according to the embodiment.

FIG. 9 shows numerical examples of the Al composition (%), the layer thickness (nm), the a-axis lattice constant a (angstrom), and the distortion (%) in each of the AlGaN barrier layer 18, the GaN buffer layer 16, and the AlGaN buffer layer 28 in the state where distortion in the GaN buffer layer 16 is zero, in the nitride based semiconductor device according to the embodiment.

FIG. 10 shows numerical examples of the Al composition (%), the layer thickness (nm), the a-axis lattice constant a (angstrom), and the distortion (%) in each of the AlGaN barrier layer 18, the GaN buffer layer 16, and the AlGaN buffer layer 28 in the state where distortion in the AlGaN buffer layer 28 is zero, in the nitride based semiconductor device according to the embodiment.

FIG. 11 is a diagram of energy band structure in close to the GaN buffer layer 16 and the AlGaN buffer layer 28 in the normal state, in the nitride based semiconductor device according to the embodiment.

FIG. 12 is a diagram of energy band structure in close to the GaN buffer layer 16 and the AlGaN buffer layer 28 in the state where distortion in the GaN buffer layer 16 is zero, in the nitride based semiconductor device according to the embodiment.

FIG. 13 is a diagram of energy band structure in close to the GaN buffer layer 16 and the AlGaN buffer layer 28 in the state where distortion in the AlGaN buffer layer 28 is zero, in the nitride based semiconductor device according to the embodiment.

FIG. 14A is a schematic cross-sectional structure diagram of a nitride based semiconductor device according to a comparative example.

FIG. 14B is a schematic cross-sectional structure diagram of the nitride based semiconductor device according to the embodiment.

FIG. 15 is a comparative diagram between energy band structure (STD) close to the GaN buffer layer and the AlGaN buffer layer in the normal state and energy band structure (A) close to the GaN buffer layer and the AlGaN buffer layer in the state where distortion in the AlGaN buffer layer is zero, in the nitride based semiconductor device according to the embodiment.

FIG. 16A is a schematic cross-sectional structure diagram of the nitride based semiconductor device according to the embodiment in which a tensile stress is introduced into the GaN buffer layer and the distortion in the AlGaN buffer layer is relaxed.

FIG. 16B is a diagram for explaining the layer thickness (nm), the Al composition (%), and the distortion corresponding to each layer shown in FIG. 16A.

FIG. 17 is a diagram of energy band structure of the nitride based semiconductor device according to the embodiment in which the distortion in the AlGaN buffer layer is relaxed and a compressive stress is further introduced into the GaN buffer layer. FIG. 18 is a diagram showing a relationship between the

Al composition x of AlₓGa₁₋ₓN and the a-axis lattice constant a, in the nitride based semiconductor device according to the embodiment.

### DESCRIPTION OF EMBODIMENTS

Next, a certain embodiment will be described with reference to drawings. In the description of the following drawings, the identical or similar reference numeral is attached to the identical or similar part. However, it should be noted that the drawings are schematic and the relation between thickness and the plane size and the ratio of the thickness of each component part differs from an actual thing. Therefore, detailed thickness and size should be determined in consideration of the following explanation. Of course, the part from which the relation and ratio of a mutual size differ also in mutually drawings is included.

Moreover, the embodiment described hereinafter merely exemplifies the device and method for materializing the technical idea; and the embodiment does not specify the material, shape, structure, placement, etc. of each component part as the following. The embodiment may be changed without departing from the spirit or scope of claims.

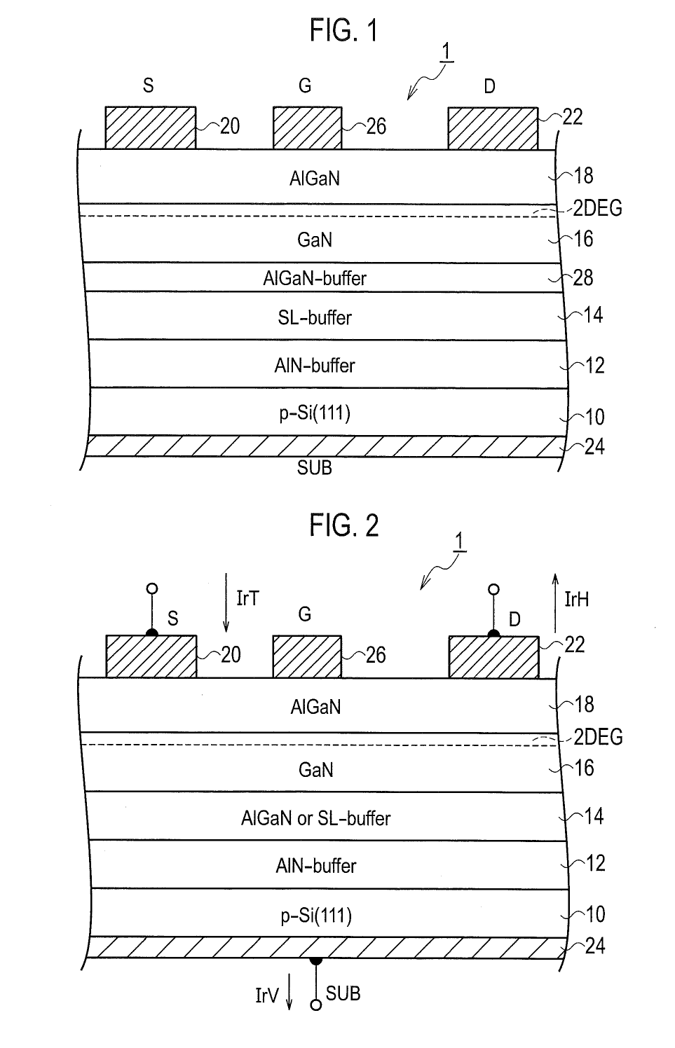

As shown in FIG. 1, a nitride based semiconductor device 1 according to an embodiment includes: a substrate 10; a first buffer layer 12 disposed on the substrate 10; a second buffer layer 14 disposed on the first buffer layer 12; a third buffer layer 28 disposed on the second buffer layer 14, the third buffer layer 28 including an AlGaN-based nitride semiconductor; a fourth buffer layer 16 disposed on the third buffer layer 28, the fourth buffer layer 16 including a GaN-based nitride semiconductor; a barrier layer 18 disposed on the fourth buffer layer 16, the barrier layer 18 including an AlGaN-based nitride semiconductor; and a source electrode 20 and a drain electrode 22, each disposed on the barrier layer 18, and a gate electrode 26 disposed between the source electrode 20 and the drain electrode 22. In the embodiment, the third buffer layer 28 is subjected to lattice relaxation.

Moreover, a back surface electrode 24 is disposed on a back surface side opposite to a front surface side of the substrate 10 where the first buffer layer 12 is disposed.

The substrate 10 includes a p type silicon (Si) having a surface orientation (111), for example.

Moreover, distortion applied to the third buffer layer 28 may be zero or a tensile strain, in the nitride based semiconductor device 1 according to the embodiment.

Moreover, distortion applied to the fourth buffer layer 16 may be zero or a compressive strain, in the nitride based semiconductor device 1 according to the embodiment.

Moreover, the third buffer layer 28 and the fourth buffer layer 16 may be doped with carbon, in the nitride based semiconductor device 1 according to the embodiment.

In particular, an interface between the third buffer layer 28 and the fourth buffer layer 16 maybe doped with carbon. Moreover, the carbon doping level may be equal to or greater than approximately 1×10¹⁷, but equal to or less than approximately 1×10²¹ (cm⁻³), for example.

The first buffer layer 12 may include AlN.

The second buffer layer 14 may be structured with a super lattice. In the embodiment, the super lattice includes a pair of an AlGaN layer used as a quantum well layer and an AlN layer used as a barrier layer. The thickness of the AlGaN layer is approximately 20 nm, and the thickness of the AlN layer is approximately 3 nm, for example.

Moreover, the third buffer layer 28 includes AlₓGa₁₋ₓN where x is Al composition, and it is preferable that x is smaller than y by equal to or greater than 10% where y is average Al composition of the super lattice of the second buffer layer 14.

Moreover, the second buffer layer 14 includes AlGaN monolayers, and the third buffer layer 28 includes AlₓGa₁₋ₓN where x is Al composition, but the Al compositions of both may be different from each other.

Moreover, the fourth buffer layer 16 may include GaN.

Moreover, the barrier layer 18 may include AlGaN.

Moreover, it is preferable that the layer thickness of the third buffer layer is equal to or greater than 100 nm.

Two Dimensional Electron Gas (2DEG) is formed in the interface between the barrier layer 18 and the fourth buffer layer 16. The barrier layer 18 including AlGaN has a role of an electron supply layer with respect to the 2DEG, and the fourth buffer layer 16 including GaN has a role of an electron transit layer. As a result, the nitride based semiconductor device 1 according to the embodiment has a transistor configuration of HEMT structure.

In the explanation hereinafter, the first buffer layer 12 is denoted as an AlN buffer layer 12, the second buffer layer 14 is denoted as an AlGaN monolayer 14 or a super lattice buffer layer 14, the third buffer layer 28 is denoted as an AlGaN buffer layer 28, the fourth buffer layer 16 is denoted as a GaN buffer layer 16, and the barrier layer 18 is denoted as an AlGaN barrier layer 18, in order to clarify the correspondence relationship between the respective layers.

FIG. 2 schematically shows a vertical leakage current IᵣV and a horizontal leakage current IᵣH with respect to a total leakage current IᵣT, in the nitride based semiconductor device 1 according to the embodiment. The AlGaN buffer layer 28 is not shown in FIG. 2 for convenience of explanation. In the nitride based semiconductor device 1 according to the embodiment, bias voltage is applied between the drain electrode 22 and the source electrode 20, and then currents respectively conducted between the source electrode 20 and the ground potential, between the drain electrode 22 and the ground potential, and between the back surface electrode 24 and the ground potential are respectively detected as a total leakage current IᵣT, a horizontal leakage current IᵣH, and a vertical leakage current IᵣV.

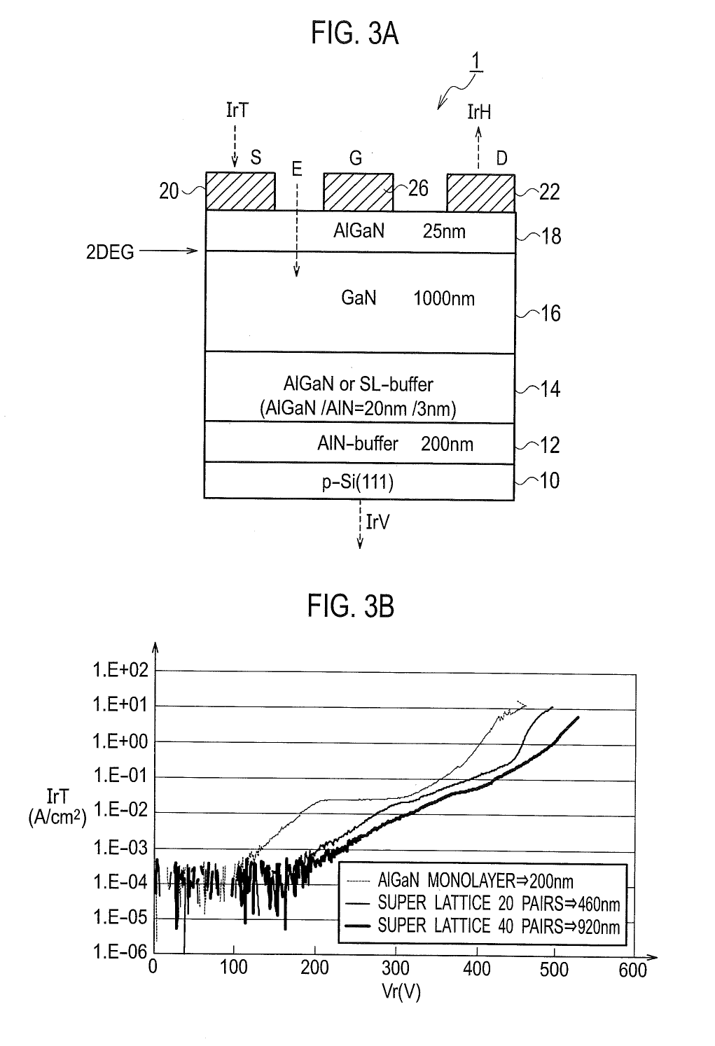

FIG. 3A shows the vertical leakage current IᵣV and the horizontal leakage current IᵣH with respect to the total leakage current IᵣT, in the case of executing etching in the arrow direction E to artificially form an OFF state of the transistor, in the nitride based semiconductor device 1 according to the embodiment. Moreover, FIG. 3B is a diagram showing a relationship between the total leakage current IᵣT and the voltage Vᵣ applied between source/drain, using the thickness of the AlGaN monolayer 14 or the super lattice buffer layer 14 as a parameter.

In the embodiment, as shown in FIG. 3B, there is a tendency to increase breakdown capability as the thickness of the second buffer layer 14 is increased, in the total leakage current IrT, where the thickness of the AlGaN monolayer 14 or super lattice buffer layer 14 is used as a parameter.

It is preferable to reduce the leakage current which flows when the transistor is OFF, in the nitride based semiconductor device 1 according to the embodiment.

As the number of pairs of the super lattices in the super lattice buffer layer 14 is increased (the total layer thickness is increased), the total leakage current IᵣT (vertical leakage current IᵣV) is also be reduced, and the breakdown voltage can also be improved.

In the embodiment, the thickness of the AIN buffer layer 12 is approximately 200 nm. The thickness of the AlGaN monolayer 14 is approximately 200 nm, and the thickness of the super lattice buffer layer 14, of which the thickness of AlGaN is 20 nm and the thickness of AlN is 3 nm, is 460 nm in the case of the number of pairs of the super lattice is 20, but is 920 nm in the case of the number of pairs thereof is 40. The thickness of the GaN buffer layer 16 is approximately 1000 nm. The thickness of the AlGaN barrier layer 18 is approximately 25 nm. Moreover, a spacing between the source electrode 20 and the drain electrode 22 is approximately 10 μm.

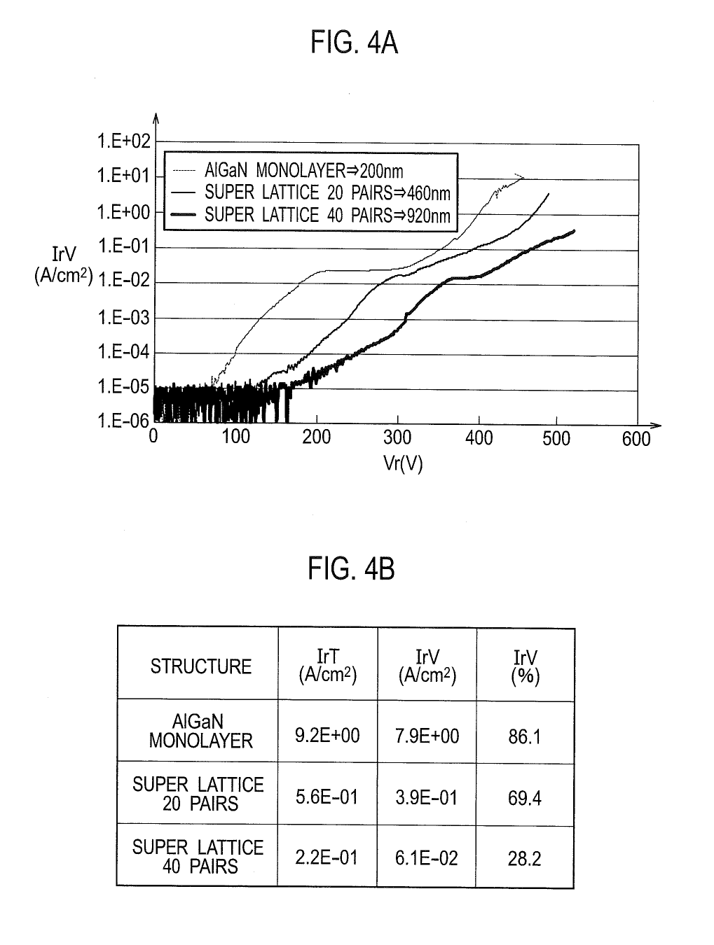

FIG. 4A shows a relationship between the vertical leakage current IᵣV and the voltage Vᵣ applied between source/drain, using the thickness of the AlGaN monolayer 14 or the super lattice buffer layer 14 as a parameter, in the nitride based semiconductor device 1 according to the embodiment.

Moreover, FIG. 4B shows a rate of the vertical component in the voltage Vᵣ=400V applied between source/drain, in the nitride based semiconductor device 1 according to the embodiment. More specifically, in the AlGaN monolayer 14, the total leakage current IᵣT is 9.2 (A/cm²), the vertical leakage current IᵣV is 7.9 (A/cm²), and the rate of the vertical component is 86.1%. In the case where the number of pairs is 20 in the super lattice buffer layer 14, the total leakage current IᵣT is 5.6×10⁻¹ (A/cm²), the vertical leakage current IᵣV is 3.9×10⁻¹ (A/cm²), and the rate of the vertical component is 69.4%. Furthermore, in the case where the number of pairs is 40 in the super lattice buffer layer 14, the total leakage current IᵣT is 2.2×10⁻¹ (A/cm²), the vertical leakage current IᵣV is 6.133 10⁻² (A/cm²), and the rate of the vertical component is 28.24%.

As clearly from FIGS. 4A and 4B, as the thicknesses of the AlGaN monolayer 14 and the super lattice buffer layer 14 is respectively increased, the vertical leakage current IᵣV is reduced and the breakdown voltage is also improved.

On the other hand, a rate of the horizontal leakage current IᵣH (=IᵣT−IᵣV) is 13.9% in the case of the AlGaN monolayer, 30.6% in the case where the number of the pairs of the super lattices is 20, or 71.8% in the case where the number of the pairs of the super lattices is 40. As clearly from FIGS. 4A and 4B, as the number of the pairs of the super lattice buffer layer 14 is increased, the vertical leakage current IᵣV is reduced and the rate of the horizontal leakage current IᵣH is also increased.

More specifically, vertical electric resistance becomes larger by increasing the layer thickness of the AlGaN monolayer 14 or the super lattice buffer layer 14, and the rate of the horizontal leakage current IᵣH through the GaN buffer layer 16 in a horizontal direction among the total leakage currents IᵣT is increased.

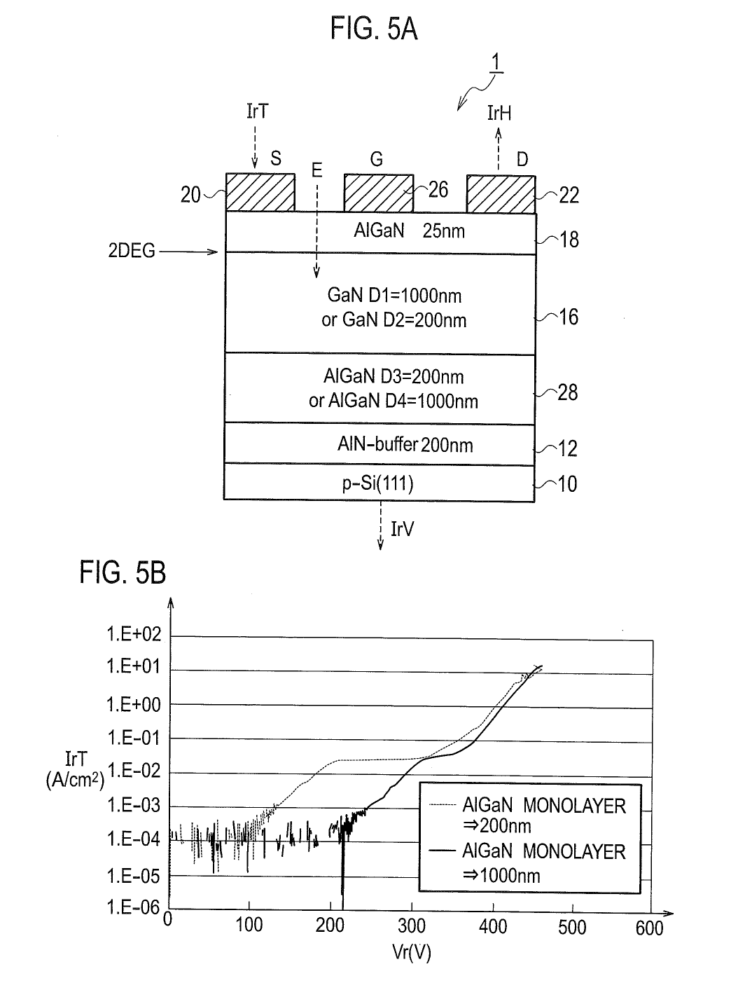

FIG. 5A shows an explanatory diagram for the vertical leakage current IᵣV and the horizontal leakage current IᵣH with respect to the total leakage current IᵣT in the case of artificially forming an OFF state of the transistor by keeping the total layer thickness constant, changing the layer thickness ratio between the GaN buffer layer 16 and the AlGaN buffer layer 28, and executing etching in the arrow direction E, in the nitride based semiconductor device 1 according to the embodiment. In FIG. 5A, the thickness of the GaN buffer layer 16 is changed to two kinds of thicknesses, thickness D1=1000 nm and thickness D2=200 nm, and the thickness of the third buffer layer 28 is changed to two kinds of thicknesses, the thickness

D3=200 nm and the thickness D4=1000 nm.

FIG. 5B shows a relationship between the total leakage current IᵣT and the voltage Vᵣ applied between source/drain in the case of keeping the total layer thickness constant, changing the thickness of the AlGaN buffer layer 28 to two kinds of thicknesses, the thickness D3=200 nm and the thickness D4=1000 nm, in the nitride based semiconductor device 1 according to the embodiment. The curved line of 200-nm-thick AlGaN monolayer corresponds to the case where the thickness D3 of the AlGaN buffer layer 28 is 200 nm, and the thickness D1 of the

GaN buffer layer 16 is 1000 nm; and the curved line of 1000-nm-thick AlGaN monolayer corresponds to the case where the thickness D3 of the AlGaN buffer layer 28 is 1000 nm, and the thickness D2 of the GaN buffer layer 16 is 200 nm. As clearly from FIGS. 5A and 5B, if the total layer thickness is constant and the layer thickness ratio between the GaN buffer layer 16 and the AlGaN buffer layer 28 is changed, the leakage current in the case of a larger layer thickness of the AlGaN buffer layer 28 is reduced. More specifically, there is a high possibility that the total leakage current IᵣT flows through the GaN buffer layer 16. The rate of the horizontal leakage current IᵣH flowing through the GaN buffer layer 16 in the horizontal direction is increased among the total leakage currents IᵣT.

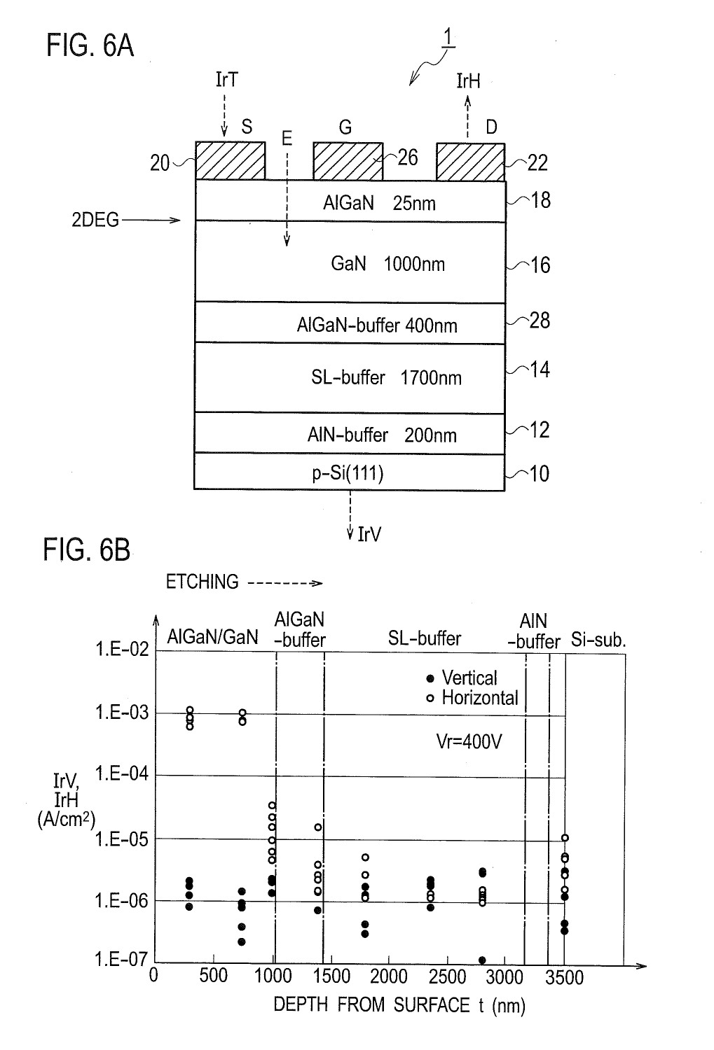

FIG. 6A shows an explanatory diagram for the vertical leakage current IrV and the horizontal leakage current IᵣH with respect to the total leakage current IᵣT in the case of artificially forming the OFF state of the transistor by executing etching in the arrow direction E, in the nitride based semiconductor device 1 according to the embodiment. In FIG. 6A, the thickness of the AIN buffer layer 12 is approximately 200 nm, for example. The thickness of the super lattice buffer layer 14 formed of super lattices (AlGaN=20 nm/AlN=3 nm) is approximately 1700 nm, for example. The thickness of the AlGaN buffer layer 28 is approximately 400 nm, for example. The thickness of the GaN buffer layer 16 is approximately 1000 nm, for example. The thickness of the AlGaN barrier layer 18 is approximately 25 nm, for example.

FIG. 6B shows a relationship between the vertical leakage current IᵣV (A/cm²) and horizontal leakage current IᵣH (A/cm²) in applied voltage 400V, and an etched depth t (nm) from the surface of the AlGaN barrier layer 18, in the configuration shown in FIG. 6A.

If the GaN buffer layer 16 is all etched as shown in FIG. 6B, the value of the horizontal leakage current IᵣH (A/cm²) is rapidly reduced. Accordingly, it is proved that a leakage path is formed in the interface between the GaN buffer layer 16 and the AlGaN buffer layer 28.

In the nitride based semiconductor device 1 according to the embodiment, a major leakage current path is formed in the interfaces between the GaN buffer layer 16 and the AlGaN buffer layer 28.

In the embodiment, compressive stress is applied to the AlGaN buffer layer 28. Accordingly, a piezo electric field is generated in the AlGaN buffer layer 28 and energy level is reduced in the interface with the GaN buffer layer 16, and thereby the leakage current path is formed.

the total leakage current IrT (A/cm2) can be reduced by controlling the strain state of the AlGaN buffer layer 28 and the GaN buffer layer 16 or by executing the C (carbon) dope to control so that the concentration of C (carbon) of the interface between the GaN buffer layer 16 and the AlGaN buffer layer 28 becomes the maximum, in the nitride based semiconductor device 1 according to the embodiment.

(Simulation of Energy Band Structure)

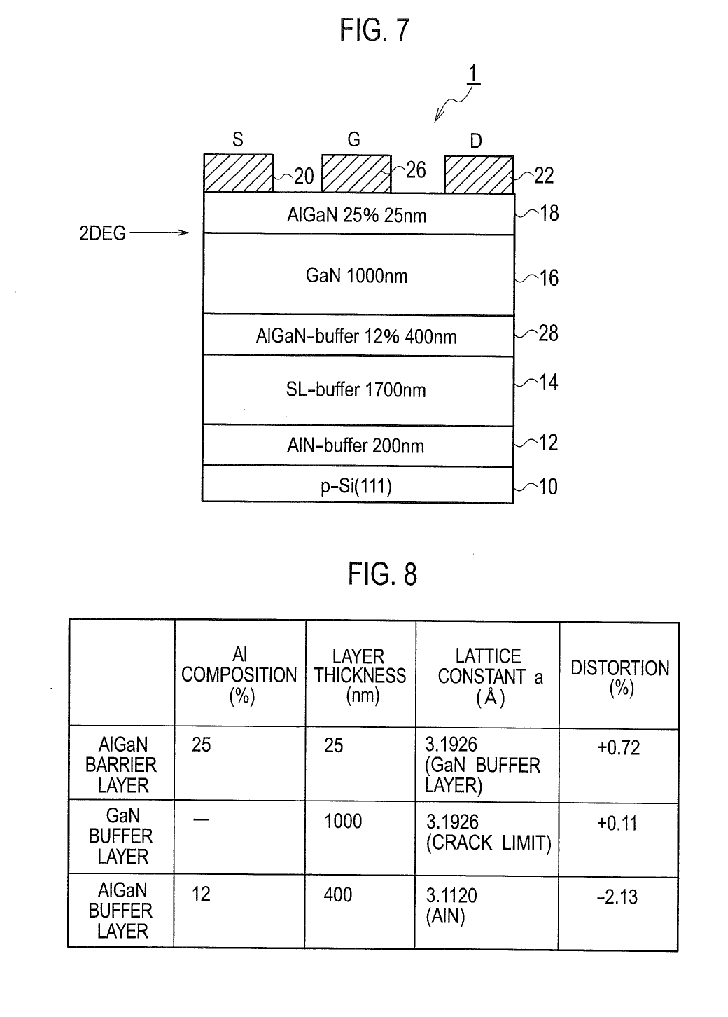

FIG. 7 shows a schematic cross-sectional structure applied to a simulation of energy band structure in the nitride based semiconductor device 1 according to the embodiment.

In FIG. 7, the thickness of the AIN buffer layer 12 is approximately 200 nm, for example. The thickness of the super lattice buffer layer 14 formed of super lattices (AlGaN=20 nm/AlN=3 nm) is approximately 1700 nm, for example. The thickness of the AlGaN buffer layer 28 formed of Al_{0.12}Ga_{0.88}N layer is approximately 400 nm, for example. The thickness of the GaN buffer layer 16 is approximately 1000 nm, for example.

The thickness of the AlGaN barrier layer 18 formed of Al_{0.25}Ga_{0.75}N layer is approximately 25 nm, for example. The 2DEG is formed in the interface between the GaN buffer layer 16 and the AlGaN barrier layer 18.

A reduction effect of the leakage current produced by the C (carbon) dope will now be explained using a simulation result of energy band structure, in the nitride based semiconductor device 1 according to the embodiment.

Attention is paid to in particular the interface between the GaN buffer layer (16) and the AlGaN buffer layer (28), in a band structure formed from an uppermost surface of the AlGaN barrier layer 18 formed of Al_{0.25}Ga_{0.75}N layer to the AlGaN buffer layer 28 formed of Al_{0.12}Ga_{0.88}N layer. Moreover, a strain state of the GaN buffer layer 16 and a strain state of the AlGaN buffer layer 28 are used as a parameter. In the embodiment, the super lattice buffer layer 14 formed of super lattices (AlGaN=20 nm/AlN=3 nm), and the AlN buffer layer 12 are used as insulators.

(Normal State)

FIG. 8 shows numerical examples of the Al composition (%), the layer thickness (nm), the a-axis lattice constant a (angstrom), and the distortion (%) in each of the AlGaN barrier layer 18, the GaN buffer layer 16, and the AlGaN buffer layer 28 in a normal state, in the nitride based semiconductor device 1 according to the embodiment. In the embodiment, the normal state corresponds to a state where no distortion control is applied to the AlGaN buffer layer 28 and the GaN buffer layer 16.

As shown in FIG. 8, in the normal state, the AlGaN barrier layer 18 formed of Al_{0.25}Ga_{0.75}N layer is completely distorted with respect to the GaN buffer layer 16. Moreover, the AlGaN buffer layer 28 formed of Al_{0.12}Ga_{0.88}N layer is completely distorted with respect to the AlN buffer layer 12. The underlying AlN buffer layer 12 is subjected to lattice relaxation, and the a-axis lattice constant a (angstrom) of the AlGaN buffer layer 28 formed of Al_{0.12}Ga_{0.88}N layer is equal to the theoretical value 3.1120 (angstrom) of AlN. Moreover, the

GaN buffer layer 16 is in a tensile strain state which is a limit state which causes a crack.

(Zero Distortion in GaN Buffer Layer)

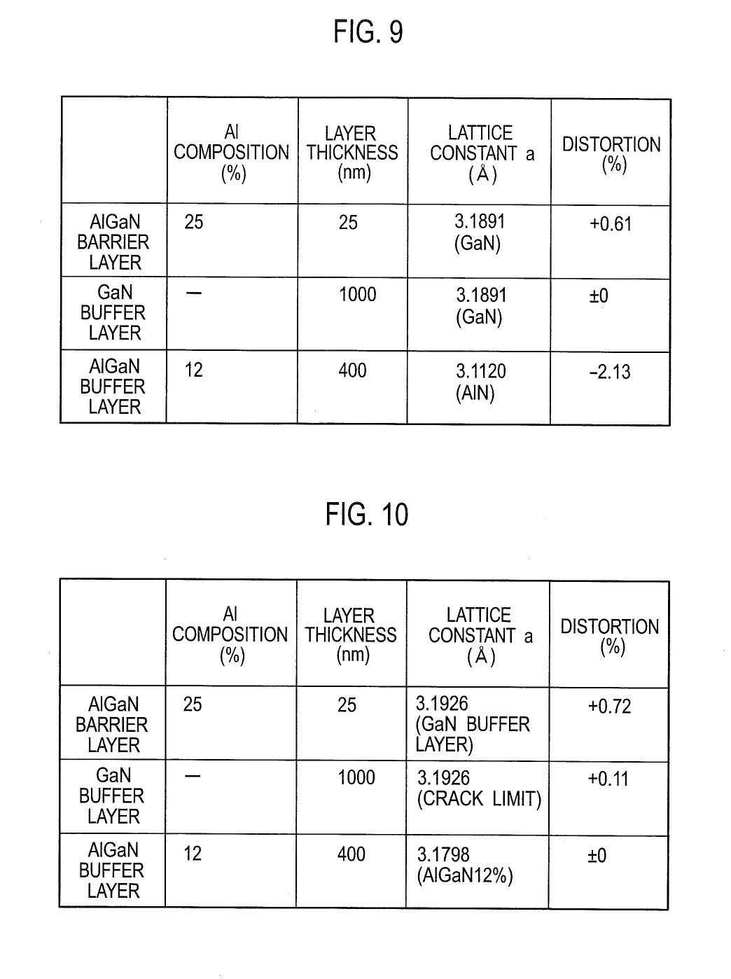

FIG. 9 shows numerical examples of the Al composition (%), the layer thickness (nm), the a-axis lattice constant a (angstrom), and the distortion (%) in each of the AlGaN barrier layer 18, the GaN buffer layer 16, and the AlGaN buffer layer 28 in the state where the distortion in the GaN buffer layer 16 is zero, in the nitride based semiconductor device 1 according to the embodiment.

As shown in FIG. 9, in the state where the distortion in the GaN buffer layer 16 is zero, the AlGaN barrier layer 18 formed of Al_{0.25}Ga_{0.75}N layer is completely distorted with respect to the GaN buffer layer 16. Moreover, the AlGaN buffer layer 28 formed of Al_{0.12}Ga_{0.88}N layer is completely distorted with respect to the AlN buffer layer 12. The underlying AlN buffer layer 12 is subjected to lattice relaxation, and the a-axis lattice constant a (angstrom) of the AlGaN buffer layer 28 is equal to the theoretical value 3.1120 (angstrom) of AlN. On the other hand, the GaN buffer layer 16 is not distorted, and the a-axis lattice constant a (angstrom) of the AlGaN buffer layer 28 is equal to a theoretical value 3.1891 (angstrom) of GaN.

(Zero distortion in AlGaN Buffer Layer)

FIG. 10 shows numerical examples of the Al composition (%), the layer thickness (nm), the a-axis lattice constant a (angstrom), and the distortion (%) in each of the AlGaN barrier layer 18, the AlGaN buffer layer 28, and the AlGaN buffer layer 28 in the state where the distortion in the GaN buffer layer is zero, in the nitride based semiconductor device 1 according to the embodiment.

As shown in FIG. 10, in the state where the distortion in the AlGaN buffer layer 28 is zero, the AlGaN barrier layer 18 formed of Al_{0.25}Ga_{0.75}N layer is completely distorted with respect to the GaN buffer layer 16. Moreover, the AlGaN buffer layer 28 formed of Al_{0.12}Ga_{0.88}N layer is not distorted, and the a-axis lattice constant a (angstrom) of the AlGaN buffer layer 28 is equal to the theoretical value 3.1798 (angstrom) of the Al_{0.12}Ga_{0.88}N layer. On the other hand, the GaN buffer layer 16 is in a tensile strain state which is a limit state which causes a crack.

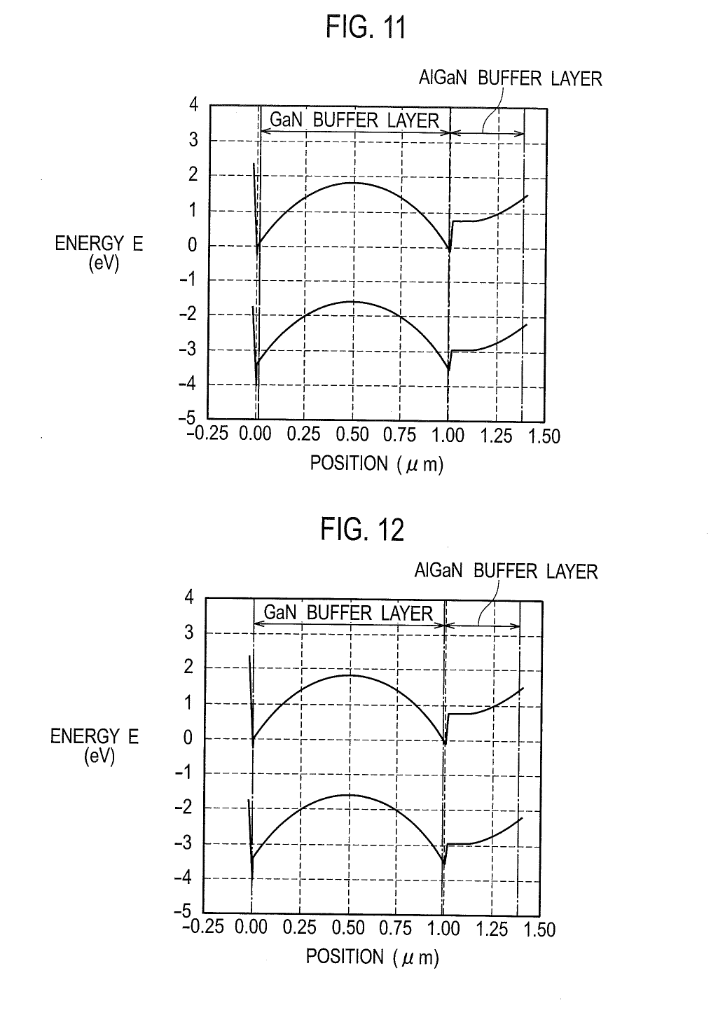

FIG. 11 shows energy band structure in close to the GaN buffer layer 16 and the AlGaN buffer layer 28 corresponding to the normal state (FIG. 8), in the nitride based semiconductor device 1 according to the embodiment.

In the normal state, a region where electrons are easily transit is generated in the interface between the GaN buffer layer 16 and the AlGaN buffer layer 28.

Moreover, since a tensile strain occurs in the GaN buffer layer 16 and a compressive strain occurs in the AlGaN buffer layer 28, a piezo electric field is generated, and thereby an energy level of the interface between the GaN buffer layer 16 and the AlGaN buffer layer 28 is reduced.

When a current which conducts the 2DEG in the interface between the AlGaN barrier layer 18 and the GaN buffer layer 16 is turned off, electrons supplied from the AlGaN barrier layer 18 to the GaN buffer layer 16 fundamentally cannot easily get over a barrier of the GaN buffer layer 16, but electrons arriving at the interface between the GaN buffer layer 16 and the AlGaN buffer layer 28 through such screw dislocation are contributed to the leakage current since dislocation, such as screw dislocation, which can become a leak path is distributed in the GaN buffer layer 16.

FIG. 12 shows energy band structure in close to the GaN buffer layer 16 and the AlGaN buffer layer 28 in the state where the distortion in the GaN buffer layer 16 is zero (FIG. 9), in the nitride based semiconductor device 1 according to the embodiment.

Also in the state where the distortion in the GaN buffer layer 16 is zero, a region where electrons are easily transit has generated in the interface between the GaN buffer layer 16 and the AlGaN buffer layer 28 in the same manner as the normal state.

Also in the state where the distortion in the GaN buffer layer 16 is zero, a compressive strain occurs in the AlGaN buffer layer 28, a piezo electric field is generated, and thereby an energy level of the interface between the GaN buffer layer 16 and the AlGaN buffer layer 28 is reduced. Comparing the energy band structure (FIG. 12) in the state where the distortion in the GaN buffer layer 16 is zero with the energy band structure (FIG. 11) in the normal state, since the distortion in the GaN buffer layer 16 in the normal state is as small as 0.11% (however, a crack is generated therein), no changes in the size of polarization are observed.

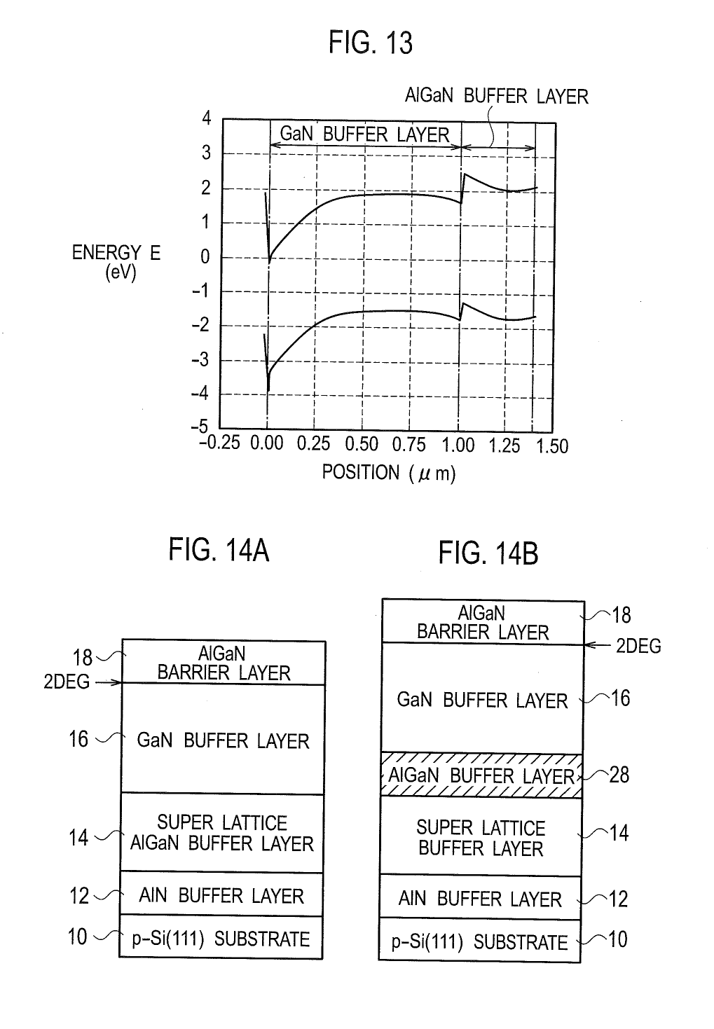

FIG. 13 shows energy band structure in close to the GaN buffer layer 16 and the AlGaN buffer layer 28 in the state where the distortion in the AlGaN buffer layer 28 is zero, in the nitride based semiconductor device 1 according to the embodiment.

In the state where the distortion in the AlGaN buffer layer 28 is zero, a tensile strain occurs in the GaN buffer layer 16, a phenomenon in which the energy level in the interface between the GaN buffer layer 16 and the AlGaN buffer layer 28 is reduced is relaxed. By making the distortion in the AlGaN buffer layer 28 into zero, the piezo electric field becomes small and thereby the energy level in the interface therebetween is increased.

A reason that the energy level of the GaN buffer layer 16 close to the interface with AlGaN buffer layer 28 is lower compared with the center portion of the GaN buffer layer 16 is the tensile strain being approximately +0.11 (%) and the spontaneous polarization in the GaN buffer layer 16.

Since the spontaneous polarization in the AlGaN buffer layer 28 is minus at a front surface side thereof, the energy level tends to increase, but the electric field intensity resulting from the tensile strain in the GaN buffer layer 16 is larger.

In the nitride based semiconductor device 1 according to the embodiment, in order to reduce the carrier density in the interface between the GaN buffer layer 16 and the AlGaN buffer layer 28, the GaN buffer layer 16 and the AlGaN buffer layer 28 are doped with carbon (C). It is effective in particular that a region to which the energy level is more reduced than that of the GaN buffer layer 16 (close to the interface between the AlGaN buffer layer 28 and the GaN buffer layer 16) due to the piezo electric field is doped with carbon (C). The doping level of carbon (C) is within a range from approximately 1×10¹⁷ (cm⁻³) to approximately 1×10²¹ (cm⁻³), for example.

A schematic cross-sectional structure of a nitride based semiconductor device according to a comparative example is expressed as shown in FIG. 14A, and a schematic cross-sectional structure of the nitride based semiconductor device according to the embodiment is expressed as shown in FIG. 14B.

In the nitride based semiconductor device according to the comparative example, the lattices of the super lattice buffer layer 14 or the AlGaN monolayer 14 are distorted to AIN buffer layer 12. As shown in FIG. 14A, the super lattice buffer layer 14 or the AlGaN monolayer 14 receives compressive stress in a plane since the super lattice buffer layer 14 or the AlGaN monolayer 14 has an a-axis lattice constant a larger than that of the AlN buffer layer 12. The above-mentioned compressive stress serves as a path of the leakage current since the energy level of the interface between the GaN buffer layer 16, and the super lattice buffer layer 14 or AlGaN monolayer 14 is reduced (piezo electric effect).

In the nitride based semiconductor device 1 according to the embodiment, the AlGaN buffer layer 28 subjected to lattice relaxation is disposed between the GaN buffer layer 16, and the super lattice buffer layer 14 or the AlGaN monolayer 14 in order to reduce the leakage current flowing through the GaN buffer layer 16 in HEMT structure.

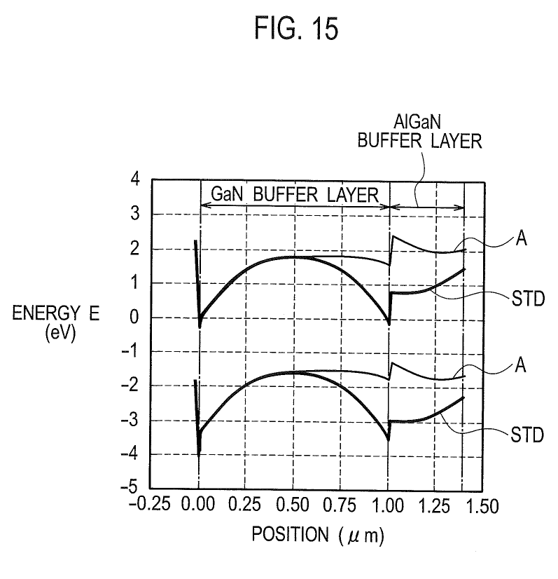

FIG. 15 shows a comparative diagram between the energy band structure (STD) in close to the GaN buffer layer 16 and the AlGaN buffer layer 28 in the normal state, and the energy band structure (curved line A) in the state where distortion in the AlGaN buffer layer 28 is zero, in the nitride based semiconductor device 1 according to the embodiment. FIG. 15 corresponds to a graph in which FIG. 11 and FIG. 13 are superposed on each other to be displayed.

In the normal state, a region where electrons are easily transit is generated in the interface between the GaN buffer layer 16 and the AlGaN buffer layer 28. Moreover, since a tensile strain occurs in the GaN buffer layer 16 and a compressive strain occurs in the AlGaN buffer layer 28, a piezo electric field is generated and thereby an energy level of the interface between the GaN buffer layer 16 and the AlGaN buffer layer 28 is reduced.

In the state where the distortion in the AlGaN buffer layer 28 is zero, a tensile strain occurs in the GaN buffer layer 16, as shown with the curved line, a phenomenon in which the energy level in the interface between the GaN buffer layer 16 and the AlGaN buffer layer 28 is reduced is relaxed. By making the distortion in the AlGaN buffer layer 28 into zero, the piezo electric field becomes small and thereby the energy level in the interface therebetween is increased. Due to the tensile strain being approximately +0.11 (%) in the GaN buffer layer 16, the energy level of the GaN buffer layer 16 close to the interface with the AlGaN buffer layer 28 is lower compared with that of the center portion of the GaN buffer layer 16.

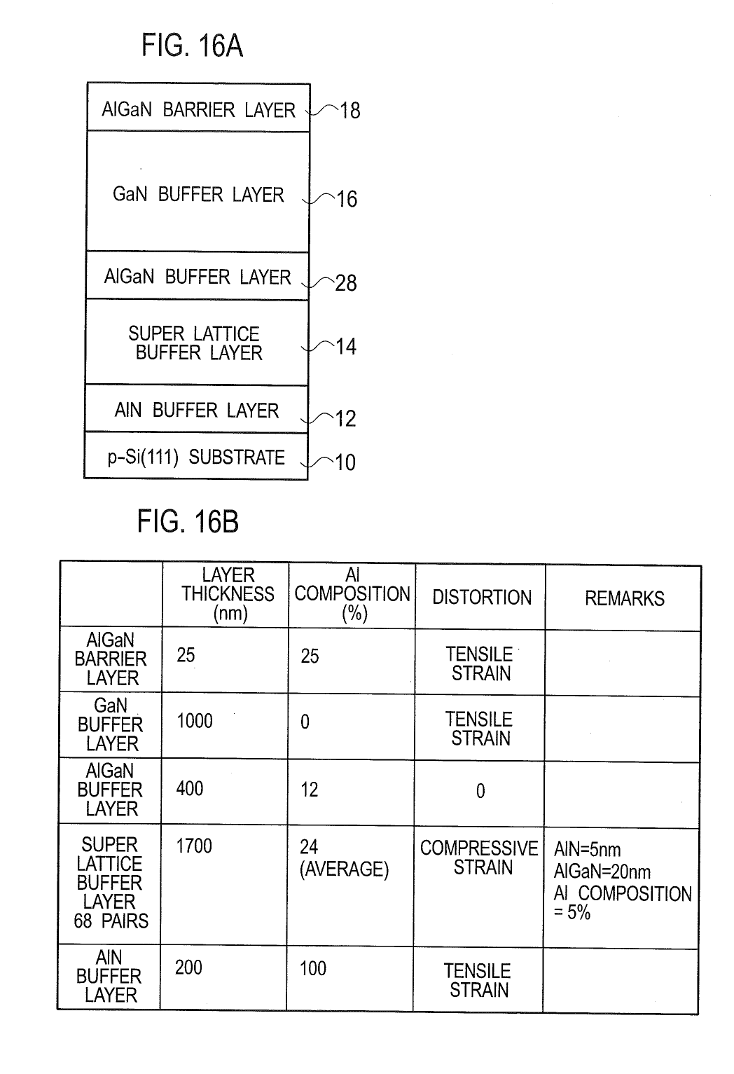

FIG. 16A shows a schematic cross-sectional structure of the nitride based semiconductor device 1 according to the embodiment in which a tensile stress is introduced into the GaN buffer layer 16 and the distortion in the AlGaN buffer layer 28 is relaxed. A state of the layer thickness (nm), the Al composition (%), and the distortion corresponding to each layer shown in FIG. 16A is expressed as shown in FIG. 16B.

The layer thickness of the AlGaN barrier layer 18 is approximately 25 nm, and the Al composition x thereof is 25%, for example. Accordingly, the AlGaN barrier layer 18 is expressed with Al_{0.25}Ga_{0.75}N. Tensile stress is applied to the AlGaN barrier layer 18.

The layer thickness of the GaN buffer layer 16 is approximately 1000 nm, for example. Tensile stress is applied to the GaN buffer layer 16.

The layer thickness of the AlGaN buffer layer 28 is approximately 400 nm, and the Al composition x thereof is 12%, for example. Accordingly, the AlGaN buffer layer 28 is expressed with Al_{0.12}Ga_{0.88}N. The distortion in the AlGaN buffer layer 28 is zero since no tensile stress and no compressive stress are applied to the AlGaN buffer layer 28.

The super lattice buffer layer 14 is formed of 68 pairs of the AlN barrier layer and the AlGaN well layer, the layer thickness thereof is approximately 1700 nm, and the average Al composition y thereof is approximately 24%, for example. The super lattice buffer layer 14 has a super lattice pair expressed with Al_{0.05}Ga_{0.95}N/AlN (the respective layer thicknesses thereof are 20 nm and 5 nm).

A magnitude relationship between the Al composition x of the AlGaN buffer layer 28 expressed with AlₓGa₁₋ₓN and the average Al composition y of the super lattice buffer layer 14 is x<y. In the embodiment, x is preferable to be smaller than y by equal to or greater than 0.1 (10%). Moreover, the layer thickness of the AlGaN buffer layer 28 expressed with AlₓGa₁₋ₓN is preferable to be equal to or greater than approximately 100 nm, for example. This is because: the more the average Al composition y of the super lattice buffer layer 14 and the Al composition x of the AlGaN buffer layer 28 are different from each other, the more the lattices of the AlGaN buffer layer 28 are easily relaxed; and the more the layer thickness of the AlGaN buffer layer 28 is increased, the more the lattices of the AlGaN buffer layer 28 are easily relaxed.

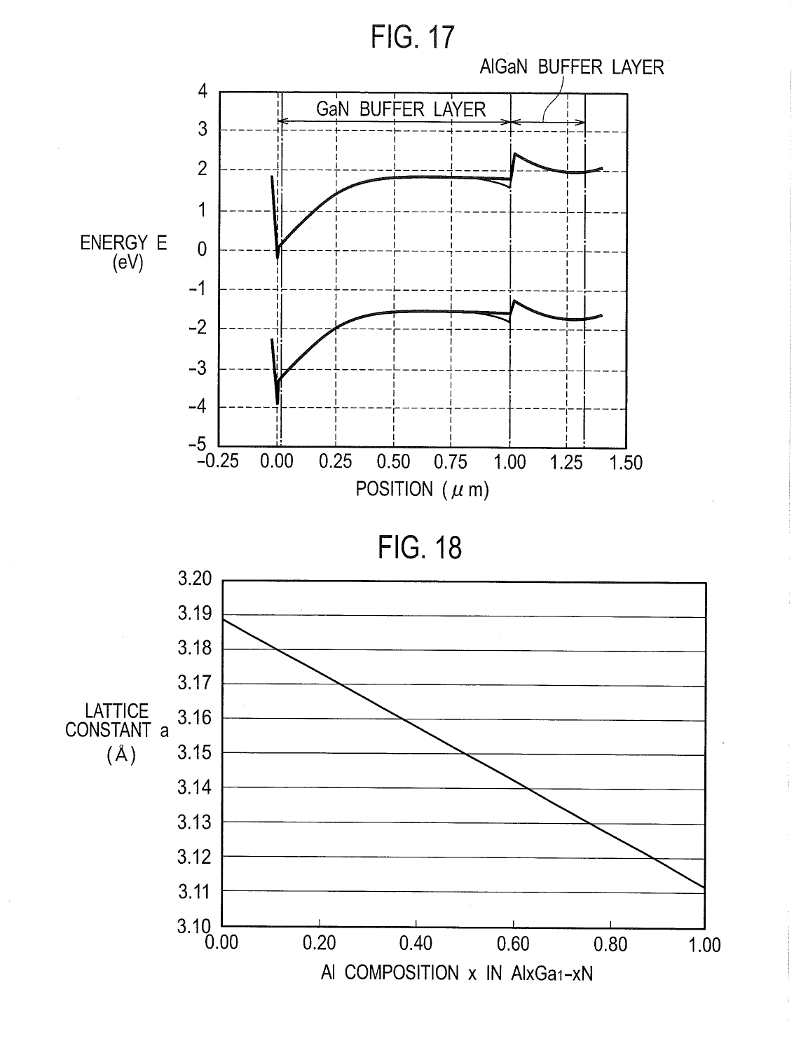

FIG. 17 shows with the thick lines an energy band structure of the nitride based semiconductor device 1 according to the embodiment in which distortion in the AlGaN buffer layer 28 is relaxed, and compressive strain is further introduced into the GaN buffer layer 16 (a piezo electric field is generated and thereby the energy level in the interface with the AlGaN buffer layer 28 is increased). In FIG. 17, the solid lines correspond to the energy band structure shown in FIG. 13 (energy band structure shown with the curved lines A in FIG. 15).

Distortion in the AlGaN buffer layer 28 is relaxed. In this case, if a Coefficient of Thermal Expansion (CTE) of the silicon substrate 10 is expressed with CTE_{Si} and a CTE of the AlGaN buffer layer 28 is expressed with CTE_{AlGaN}, a relationship of CTE_{Si}<CTE_{AlGaN} is satisfied, and therefore the AlGaN buffer layer 28 is easy to receive tensile stress.

The potential structure without fall of potential in the interface between the GaN buffer layer 16 and the AlGaN buffer layer 28 is realizable by relaxing the distortion in the AlGaN buffer layer 28, and further introducing the tensile stress thereinto.

FIG. 18 shows a relationship between the Al composition x of AlₓGa₁₋ₓN layer and the a-axis lattice constant a, in the nitride based semiconductor device 1 according to the embodiment. For example, the a-axis lattice constant a of the AlN is 3.1120, the a-axis lattice constant a of the GaN is 3.1891, and the a-axis lattice constant a of the Al_{0.12}Ga_{0.88}N is 3.1798.

As explained above, according to the embodiment, there can be provided the nitride based semiconductor device capable of reducing the leakage current and improving the breakdown capability.

### OTHER EMBODIMENTS

As explained above, the embodiment has been described, as a disclosure including associated description and drawings to be construed as illustrative, not restrictive. This disclosure makes clear a variety of alternative embodiment, working examples, and operational techniques for those skilled in the art.

Such being the case, the embodiment covers a variety of embodiments, whether described or not.

### INDUSTRIAL APPLICABILITY

The nitride based semiconductor device according to the embodiment is available in all over power devices, such as high-frequency power semiconductor modules, high-frequency intelligent power modules, etc. The nitride based semiconductor device according to the embodiment is applicable in particular to wireless power supply receiver-transmitter devices, mobile phones, digital cameras, video cameras, tablet-type devices, electric vehicles, desktop computers, printers, television sets, notebook computers, docking stations, home servers, etc.; and also to inverters, converters, etc. used for solar cells and industrial equipment, as fields currently required for high-frequency waves and reduction in size and weight.

What is claimed is:

1. A nitride based semiconductor device comprising:
a substrate;
a first buffer layer disposed on the substrate;
a second buffer layer disposed on the first buffer layer;
a third buffer layer disposed on the second buffer layer, the third buffer layer comprising an AlGaN-based nitride semiconductor;
a fourth buffer layer disposed on the third buffer layer, the fourth buffer layer comprising a GaN-based nitride semiconductor;
a barrier layer disposed on the fourth buffer layer, the barrier layer comprising an AlGaN-based nitride semiconductor; and
a source electrode and a drain electrode, each disposed on the barrier layer, and a gate electrode disposed between the source electrode and the drain electrode, wherein
the third buffer layer is subjected to lattice relaxation.

2. The nitride based semiconductor device according to claim 1, wherein
distortion applied to the third buffer layer is zero or tensile strain.

3. The nitride based semiconductor device according to claim 1, wherein
distortion applied to the fourth buffer layer is zero or compressive strain.

4. The nitride based semiconductor device according to claim 2, wherein
distortion applied to the fourth buffer layer is zero or compressive strain.

5. The nitride based semiconductor device according to claim 1, wherein
the third buffer layer and the fourth buffer layer are doped with carbon.

6. The nitride based semiconductor device according to claim 1, wherein
an interface between the third buffer layer and the fourth buffer layer is doped with carbon.

7. The nitride based semiconductor device according to claim 5, wherein
a carbon doping level is equal to or greater than 1×10¹⁷, but equal to or less than 1×10²¹ (cm⁻³).

8. The nitride based semiconductor device according to claim 6, wherein
a carbon doping level is equal to or greater than 1×10¹⁷, but equal to or less than 1×10²¹ (cm⁻³).

9. The nitride based semiconductor device according to claim 1, wherein
the first buffer layer comprises AlN.

10. The nitride based semiconductor device according to claim 1, wherein
the second buffer layer comprises a super lattice.

11. The nitride based semiconductor device according to claim 10, wherein
the super lattice comprises a pair of an AlGaN layer and an AlN layer.

12. The nitride based semiconductor device according to claim 11, wherein
the third buffer layer comprises AlₓGa₁₋ₓN where x is Al composition, and x is smaller than y by equal to or greater than 10% where y is average Al composition of the super lattice.

13. The nitride based semiconductor device according to claim 1, wherein
the second buffer layer comprises an AlGaN monolayer, and the third buffer layer comprises AlₓGa₁₋ₓN where x is Al composition, but the Al compositions of both are different from each other.

14. The nitride based semiconductor device according to claim 1, wherein
the fourth buffer layer comprises GaN.

15. The nitride based semiconductor device according to claim 1, wherein
the layer thickness of the third buffer layer is equal to or greater than 100 nm.

16. The nitride based semiconductor device according to claim 1, wherein
the substrate comprises p-type Si having a surface orientation (111).
